(19) United States
(12) Patent Application Publication
(10) Pub. No.: US 2010/0181640 A1
(43) Pub. Date: Jul. 22, 2010

(54) SEMICONDUCTOR DEVICE

(75) Inventors: Tatsuya SHIROMOTO, Tokyo (JP); Tetsuya Nitta, Tokyo (JP); Shigeo Tokumitsu, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/690,714

(22) Filed: Jan. 20, 2010

(30) Foreign Application Priority Data
Jan. 20, 2009 (JP) 2009-010202

(51) Int. Cl. H01L 29/06

(52) U.S. Cl. 257/506; 257/E29.02

(57) ABSTRACT

Provided is a semiconductor device about which the reliability thereof is certainly kept even when a void is generated in a buried film in its trench. A rectangular element formation region is formed in a silicon layer. A trench having a predetermined width is formed to surround the element formation region. A first TEOS film and a second TEOS film are buried in the trench. A protecting film is formed at an L-shaped intersection region of the trench.

### CROSS-REFERENCE TO RELATED APPLICATION

The disclosure of Japanese Patent Application No. 2009-10202 filed on Jan. 20, 2009 including the specification, drawings and abstract is incorporated herein by reference in its entirety.

### BACKGROUND OF THE INVENTION

The present invention relates to a semiconductor device, in particular, a semiconductor device having a relatively deep trench.

In MOSFETs (metal oxide semiconductor field effect transistors) used in, for example, automobiles as semiconductor elements, a relatively high voltage of several tens of volts to several hundreds of volts is controlled. In order to control such a voltage, semiconductor elements are required to have a high voltage resistance, and the periphery of the semiconductor elements needs to be surrounded by an insulating film having a high voltage resistance characteristic.

As one kind of wafer in which semiconductor elements are formed, an SOI (silicon-on-insulator) wafer is known. In an SOI wafer, a silicon layer is formed over a silicon substrate to interpose an insulating film therebetween. This insulating film is called a BOX (buried oxide) layer. In order to keep a high voltage resistance certainly in the case of using an SOI wafer, a deep trench reaching a BOX layer is made and then an insulating film, a polysilicon film, or the like is formed inside the trench.

A method for making this trench is a method of subjecting the silicon layer on the SOI wafer to reactive dry etching to make the trench. In the meantime, in an ordinary silicon substrate that is not any SOI wafer, an electrically isolating structure may be used wherein a deep trench and a PN junction are combined with each other. About the deep trench, it is reported that in order that an insulating film or the like can be satisfactorily filled into the trench, it is preferred to make the trench into a forward tapered form such that a hole is made wider toward its open end.

A method for burying an insulating film or the like into such a deep trench is as follows: first, silicon surfaces exposed to side walls of a trench made in an SOI wafer or the like are subjected to thermally oxidizing treatment, or a TEOS (tetraethoxy orthosilicate) film is formed onto side walls of the trench by thermal CVD (chemical vapor deposition); next, a non-doped polysilicon film is formed to be buried into the trench; and by thermal CVD, a TEOS film may be further formed, besides the non-doped polysilicon film, so as to be buried into the trench.

After the non-doped polysilicon film or the TEOS film is buried in the trench, unnecessary portions of the polysilicon film or the TEOS film are etched back by reactive dry etching, so as to be removed, or are polished by chemical mechanical polishing (CMP). In this way, a trench isolation structure is completed, wherein the polysilicon film or the like is buried in the trench. Documents disclosing such a trench isolation structure are, for example, the following Patent Documents 1 and 2:

Japanese Unexamined Patent Publication No. 2003-324194

Japanese Unexamined Patent Publication No. 2005-116907

### SUMMARY OF THE INVENTION

However, conventional semiconductor devices have problems as described hereinafter. In many cases, a film, for burying, that is used to be buried into a trench is a polysilicon film formed by thermal CVD, which is relatively good in coverage. Considering insulating property and leakage resistance against high voltages, which may reach several hundreds of voltages, productivity, and other properties required for high voltage-resistant semiconductor elements used, a TEOS film formed by thermal CVD may be used.

When a TEOS film is formed in trenches by thermal CVD, the growth rate of the TEOS film tends to be higher near the open end of the trenches than inside the trenches. Therefore, in the middle of the growth of the TEOS film, the open ends of the trenches are closed with the TEOS film so that the TEOS film may not be grown in the trenches. Thus, hollow voids may be made in the trenches. The voids are easily made in regions having a relatively large width, for example, intersection regions of the trenches, and corner regions of the trenches, such as bent regions of the trenches.

When the voids are made in the TEOS film in the trenches, the voids may be exposed in a case where after the formation of the TEOS film, unnecessary portions of the TEOS film are etched back or subjected to chemical mechanical polishing so as to be removed. When the voids are exposed, a washing solution, a chemical liquid, or the like may retain in the exposed voids in a washing step and an etching step that are to be subsequently performed. Thus, the retaining washing solution or chemical liquid may act as a source for generating alien substances, or produce an adverse effect on the interconnections. Thus, the reliability of the semiconductor device may be damaged.

In order to solve the problems, the present invention has been made, and an object thereof is to provide a semiconductor device about which even when voids are generated in a buried film inside its trench, the reliability of the device is not damaged.

The semiconductor device according to the invention has an element formation region, a trench, a buried film, and a protective film. The element formation region is formed in a main surface of a semiconductor substrate. The trench is configured to surround the element formation region. The buried film is formed in the trench. The protective film is formed to cover a region of the buried film that is buried in a corner region of the trench.

According to the semiconductor device according to the invention, a protective film is formed at a corner region of its trench, where the trench width is relatively large and voids are said to be easily generated in a buried film buried into the trench. This manner makes it possible to restrain the generation of inconveniences resulting from a washing solution, a chemical liquid or the like that retains in the voids. As a result, a high reliability of the semiconductor device can be certainly kept.

### BRIEF DESCRIPTION OF THE DRAWINGS

FIG. 1 is a sectional view illustrating one step in a process for producing a semiconductor device according to an embodiment of the invention.

FIG. 2 is a sectional view illustrating a step performed after the step illustrated in FIG. 1 in the embodiment.

FIG. 3 is a sectional view illustrating a step performed after the step illustrated in FIG. 2 in the embodiment.

FIG. 4 is a sectional view illustrating a step performed after the step illustrated in FIG. 3 in the embodiment.

FIG. 5 is a sectional view illustrating a step performed after the step illustrated in FIG. 4 in the embodiment.

FIG. 6 is a sectional view illustrating a step performed after the step illustrated in FIG. 5 in the embodiment.

FIG. 7 is a sectional view illustrating a step performed after the step illustrated in FIG. 6 in the embodiment.

FIG. 8 is a sectional view illustrating a step performed after the step illustrated in FIG. 7 in the embodiment.

FIG. 9 is a sectional view illustrating a step performed after the step illustrated in FIG. 8 in the embodiment.

FIG. 10 is a sectional view illustrating a step performed after the step illustrated in FIG. 9 in the embodiment.

FIG. 11 is a sectional view illustrating a case where a void is generated in a TEOS film in the step illustrated in FIG. 8 in the embodiment.

FIG. 12 is a sectional view illustrating state that the void is made exposed through a step performed after the step illustrated in FIG. 11 in the embodiment.

FIG. 13 is a sectional view illustrating a step performed after the step illustrated in FIG. 12 in the embodiment.

FIG. 14 is a sectional view illustrating a step performed after the step illustrated in FIG. 13 in the embodiment.

FIG. 15 is a sectional view illustrating a step performed after the step illustrated in FIG. 14 in the embodiment.

FIG. 16 is a sectional view illustrating a step performed after the step illustrated in FIG. 15 in the embodiment.

FIG. 17 is a perspective sectional view illustrating a step corresponding to the step illustrated in FIG. 16 in a case where no protective film is formed in the embodiment.

FIG. 18 is a plan view illustrating a first example of an arrangement pattern of one or more trenches in the embodiment.

FIG. 19 is a sectional view taken on cross section line XIX-XIX in FIG. 18 in the embodiment.

FIG. 20 is a second plan view illustrating a second example of the trench arrangement pattern in the embodiment.

FIG. 21 is a sectional view taken on cross section line XXI-XXI in FIG. 20 in the embodiment.

FIG. 22 is a perspective sectional view illustrating a case where a void is generated in a cross region of trenches in the embodiment.

FIG. 23 is a perspective sectional view illustrating a case where a void is generated in an L-shaped region of a trench in the embodiment.

FIG. 24 is a sectional view of a semiconductor device according to a modified example in the embodiment.

### DETAILED DESCRIPTION OF THE PREFERRED EMBODIMENTS

A semiconductor device according to an embodiment of the invention will be described hereinafter, giving, as an example, a semiconductor device having one or more trenches) that (each) has/have a predetermined width so as to surround a rectangular element formation region. In the present specification, such a trench is referred to merely as a rectangular trench. First, a process for producing the semiconductor device will be described.

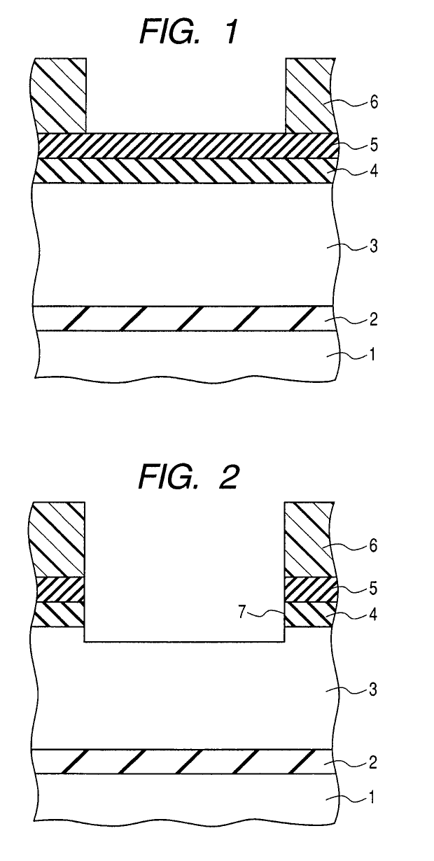

As illustrated in FIG. 1, as a substrate, an SOI substrate is used wherein a silicon layer 3 is formed over a supporting substrate 1 to interpose a buried oxide film 2 therebetween. On the surface of the silicon layer 3 of the SOI substrate is formed a silicon oxide film 4. On the surface of the silicon oxide film 4 is formed a silicon nitride film 5. On the surface of the silicon nitride film 5 is formed a resist pattern 6 for forming a field oxide film.

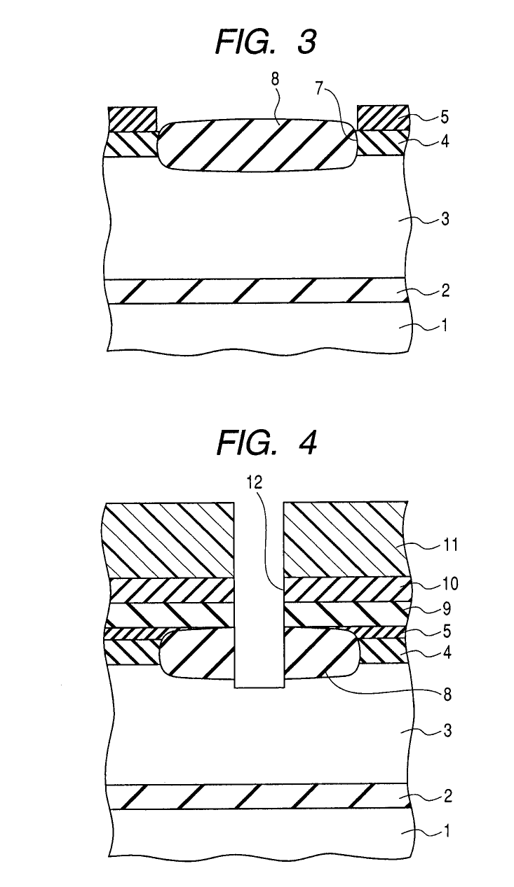

Next, as illustrated in FIG. 2, the workpiece is dry-etched, using the resist pattern 6 as a mask so as to make an opening 7, which is typical one out of plural openings, but may be a single opening. The opening 7 penetrates through the silicon nitride film 5 and the silicon oxide film 4 to make the silicon layer 3 exposed. Thereafter, the resist pattern 6 is removed. Next, as illustrated in FIG. 3, the workpiece is subjected to oxidizing treatment to form a field oxide film 8, which is the above-mentioned field oxide film, in a silicon layer 3 region exposed to the opening 7.

Next, as illustrated in FIG. 4, a silicon nitride film 9 is further formed on the surface of the silicon nitride film 5 to cover the field oxide film 8. On the surface of the silicon nitride film 9 is formed a TEOS film 10. On the surface of the TEOS film 10 is formed a resist pattern 11 for making deep trenches. Next, the resist pattern 11 is used as a mask to dry-etch the workpiece to make openings which penetrate through the TEOS film 10, the silicon nitride film 9 and the field oxide film 8 to make the silicon layer 3 exposed, thereby forming a trench-forming mask 12. Thereafter, the resist pattern 11 is removed.

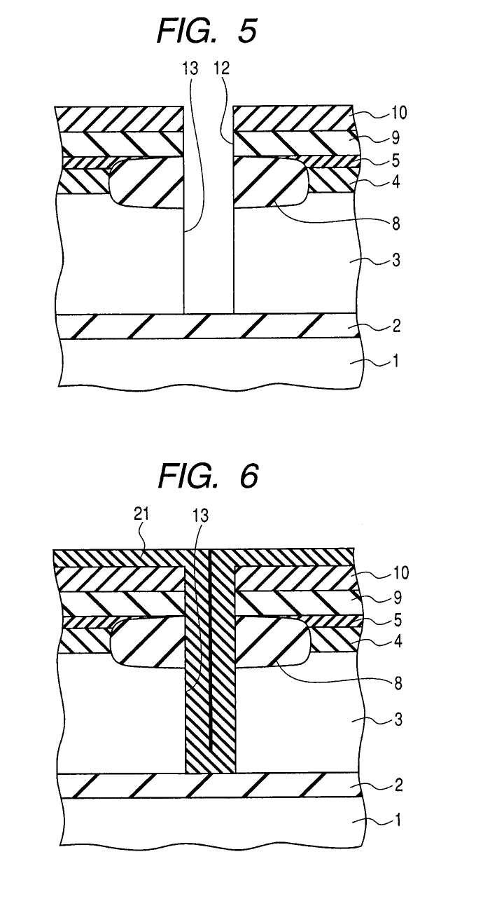

Next, as illustrated in FIG. 5, the trench-forming mask 12 is used as a mask to dry-etch the workpiece, thereby forming a trench 13, which is typical one of the above-mentioned trenches but may be a single trench, penetrating through the silicon layer 3 to reach the buried oxide film 2. The trench is specifically described herein. This trench, which is used in the semiconductor device, is so-called a deep trench, which is a relatively deep trench having an aspect ratio (ratio of the width/the depth) of about 1/10 to 1/5. In the case of the SOI substrate, the depth of the trench 13 corresponds substantially to the thickness of the silicon layer 3. In the case of making, as the trench 13, a trench reaching the buried oxide film 2 in a silicon layer having a thickness of about 5 to 10 μm as the silicon layer 3, a voltage resistance of about 100 to 200 V can be obtained.

Next, as illustrated in FIG. 6, a first TEOS film 21 having a film thickness permitting the TEOS film 21 to be buried in the trench 13 is formed by CVD. In the case of trying to cover in a deep trench, the trench cannot be sufficiently covered in by a high density plasma (HDP) method usable in the case of covering in a relatively shallow trench (i.e., a shallow trench isolation:STI), which has an aspect ratio of about 1/2. For this reason, in order to cover in a deep trench, a TEOS film, which is said to be relatively good in coverage, is used. At this stage, the workpiece may be subjected to thermal treatment to density the first TEOS film 21 thermally if necessary.

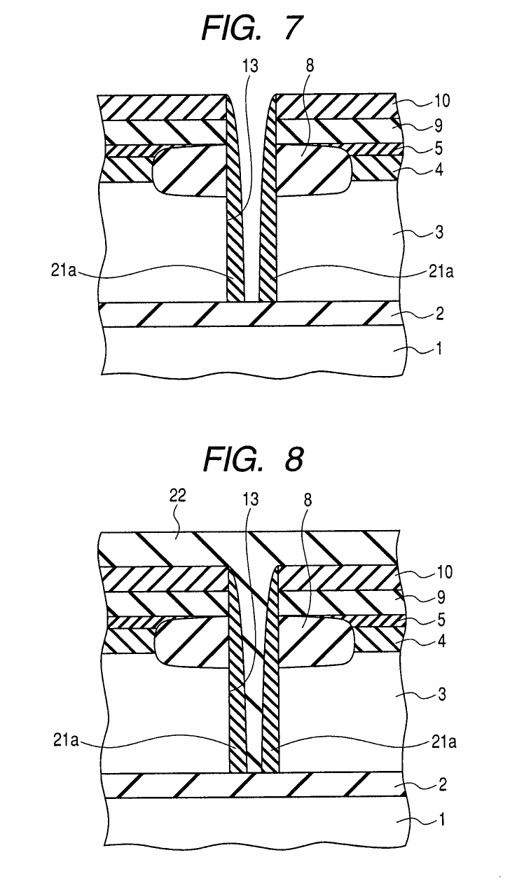

Next, as illustrated in FIG. 7, the first TEOS film 21 is subjected to anisotropic etching to remove the first TEOS film 21 except first TEOS film regions 21a positioned on side walls of the trench 13. Next, as illustrated in FIG. 8, by CVD, a second TEOS film 22 is further formed to be buried into the trench 13.

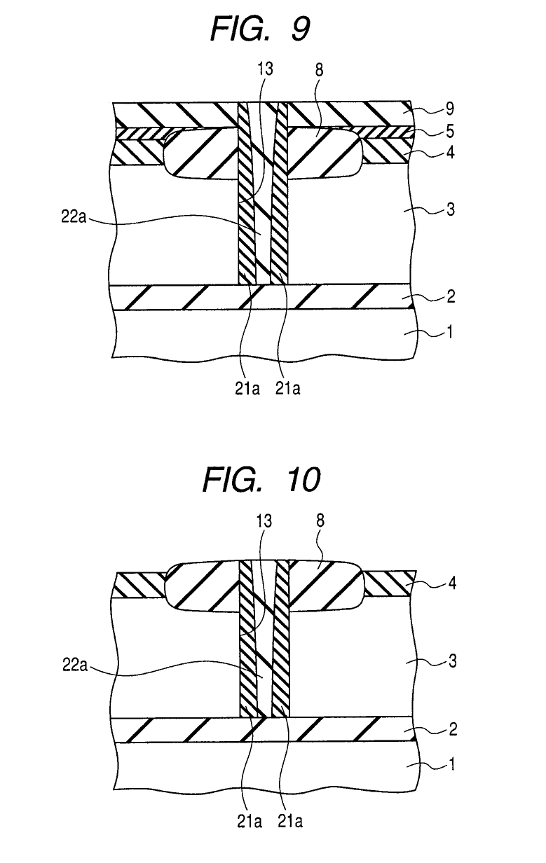

Next, as illustrated in FIG. 9, the workpiece is polished by chemical mechanical polishing to remove second TEOS film 22 regions, the TEOS film 10, and others that are positioned over the upper surface of the silicon nitride film 9 while the first TEOS film regions 21a and a second TEOS film region 22a are caused to remain. Next, as illustrated in FIG. 10, the silicon nitride film 9 and the silicon nitride film are removed. At this stage, a trench isolation structure is formed.

Voids that may be made in the trench are described herein. The growth rate of the second TEOS film 22 tends to be higher near the open end of the trench 13 than inside the trench 13. For this reason, in the middle of the growth of the second TEOS film 22, the open end of the trench 13 is closed with the second TEOS film 22 so that the TEOS film may not be grown in the trench 13. Thus, hollow voids may be made in the trench 13.

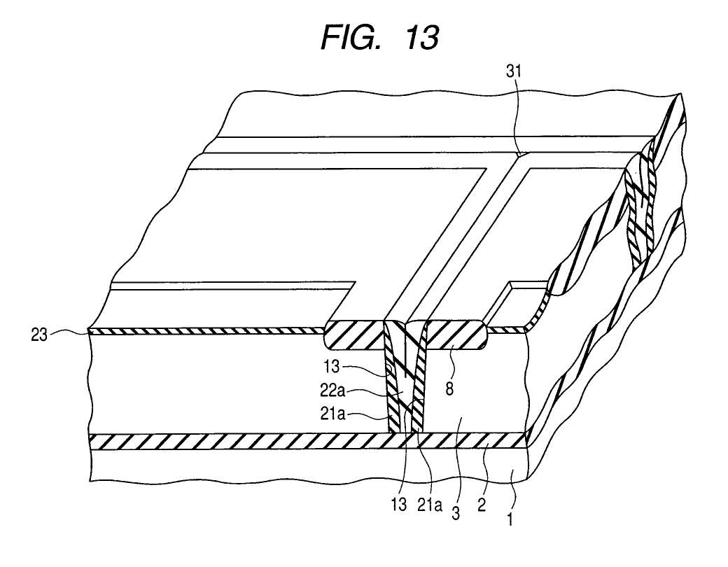

When the planar form of trenches is rectangular (see, for example, FIG. 18), the width of corner regions of the trenches is larger than regions of the trenches that are extended in a straight line form. For example, about an intersection region where a straightly-extended trench region intersects another straightly-extended trench region into a T-shaped form (see FIG. 13), the width thereof is larger than that of the straightly-extended regions.

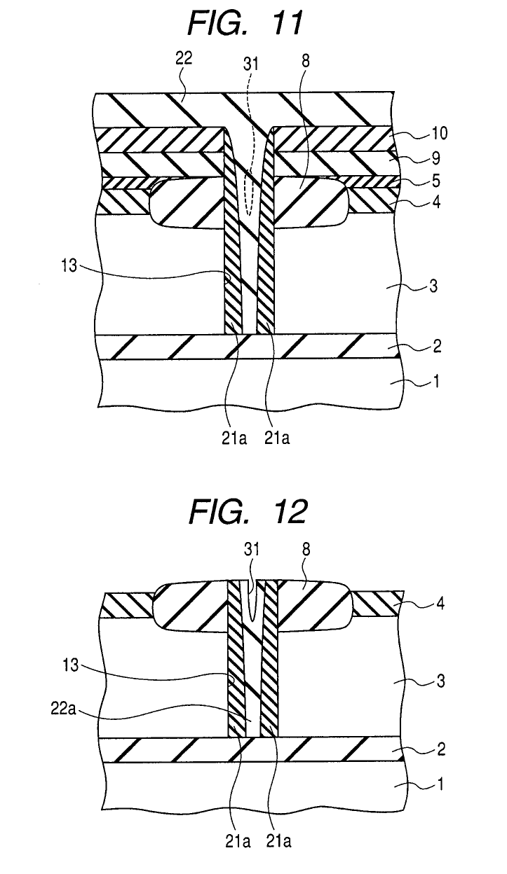

In each of such trench regions having a relatively small width, second TEOS film regions growing on opposing side walls of the trench, respectively, may contact each other; at the time of the contact, in each of the trench regions having a relatively large width, second TEOS film regions growing on opposing side walls of the trench, respectively, do not contact each other yet so that a depression such as a valley is made in the second TEOS film. When the growth of the second TEOS film advances near the open end of the depression, the depression is covered with the second TEOS film so that the depression turns a void as represented by reference number 31 in FIG. 11, and the void remains.

In this state, which can be illustrated in FIG. 11, chemical mechanical polishing is utilized to remove the second TEOS film 22 region, the TEOS film 10 and others that are positioned over the upper surface of the silicon nitride film 9. As a result, the void 31 generated in the second TEOS film 22 may be exposed as illustrated in FIGS. 12 and 13. FIG. 13 illustrates a state at the time when a gate oxide film is formed, which will be described also later.

Next, on the supposition that the void 31 is exposed at a T-shaped intersection region as a corner region of the trench 13, producing steps performed after the above-mentioned steps will be described hereinafter. After the chemical mechanical polishing, the workpiece is subjected to oxidizing treatment to form a sacrificial oxide film (not illustrated) in the exposed silicon layer region. Next, an impurity ion of a predetermined conductive type is implanted across the sacrificial oxide film into the workpiece to form a well (not illustrated) of the predetermined conductive type. Next, the workpiece is subjected to a predetermined thermal treatment to activate the well. Next, the sacrificial oxide film is removed.

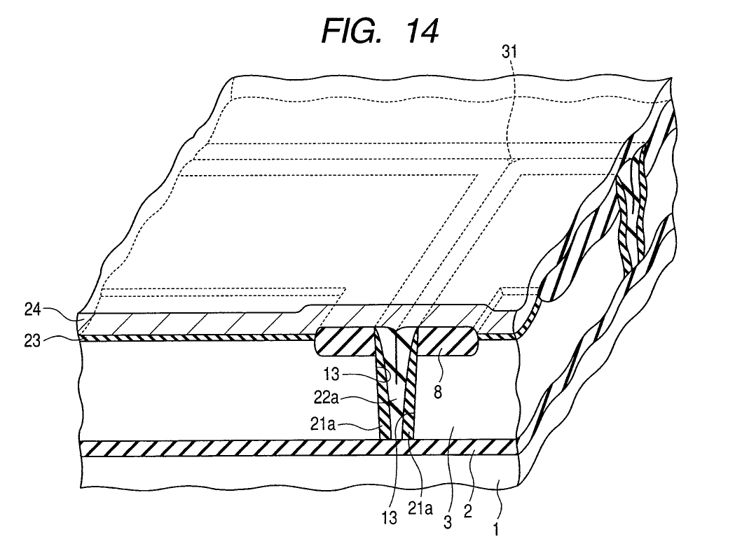

Next, as illustrated in FIG. 13, the workpiece is subjected to thermally oxidizing treatment to form a gate oxide film 23 on the exposed silicon layer 3 region. Next, as illustrated in FIG. 14, a conductive film 24, which is to be gate electrodes, is formed to cover the gate oxide film 23. The formed conductive film 24 is, for example, made of a polysilicon film and a tungsten silicide film. A TEOS film (not illustrated) is formed on the conductive film 24.

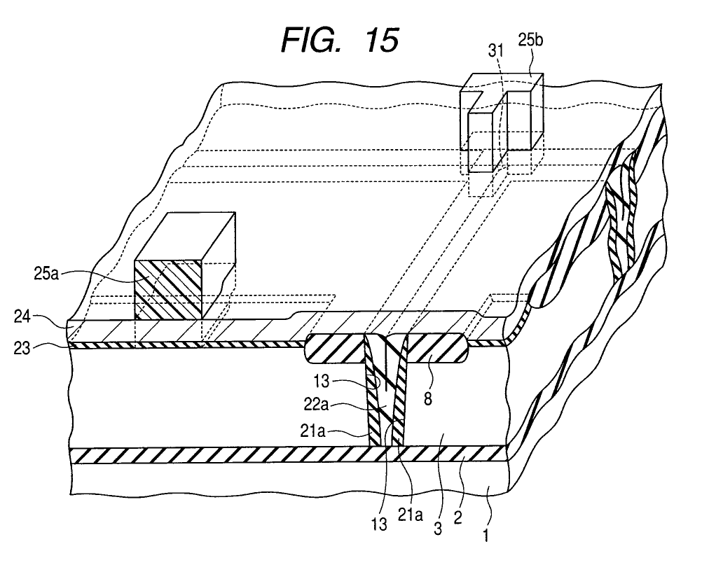

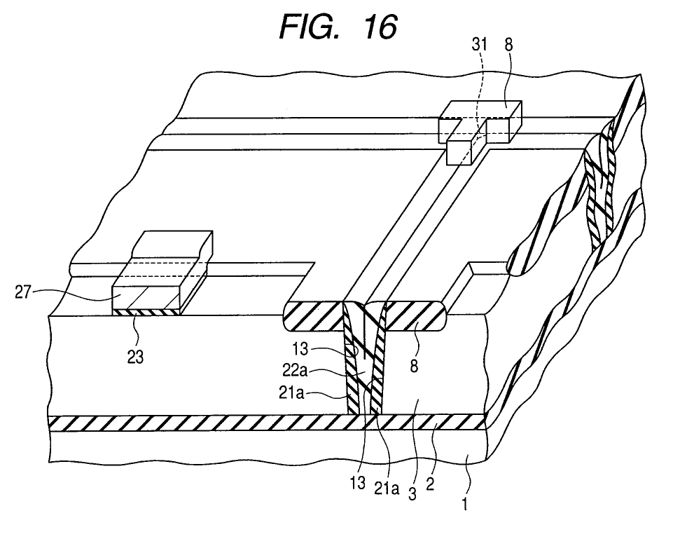

Next, as illustrated in FIG. 15, on the conductive film 24 are formed a resist pattern 25a for forming the gate electrodes and a resist pattern 25b for forming a protecting film for covering the void 31. Next, the resist pattern 25a and the resist pattern 25b are used as a mask to subject the conductive film 24 and the others to anisotropic etching to form a gate electrode 27, which is one of the gate electrodes, and a protecting film 28, which is the protecting film, as illustrated in FIG. 16. The protecting film 28 formed at the same time of forming the gate electrode 27 is conductive. Therefore, in order to keep electrical insulation therebetween, it is preferred that the protecting film 28 is formed in a region where the trench is arranged.

Thereafter, the gate electrode 27 and so on are used as a mask to implant an impurity of a predetermined conductive type into the silicon layer 3 to form a source/drain region (not illustrated). In this way, a principal portion of a semiconductor element is formed.

As illustrated in FIG. 16, in the semiconductor device produced by the above-mentioned producing process, the protecting film 28 is formed at the T-shaped intersection region as a corner region of the trench 13. This manner makes it possible that even when a washing solution, a chemical liquid or the like retains in the exposed void 31 in a washing step or an etching step performed after the void 31 is made exposed, the void 31 is covered with the protecting film 28 to prevent the retaining washing solution or chemical liquid from acting as a source for generating alien substances or prevent the chemical liquid and so on from producing an adverse effect onto the interconnections (i.e., interconnections to be formed in the semiconductor device). In any step after the protecting film 28 is formed, the washing solution, the chemical liquid or the like never invades the void 31.

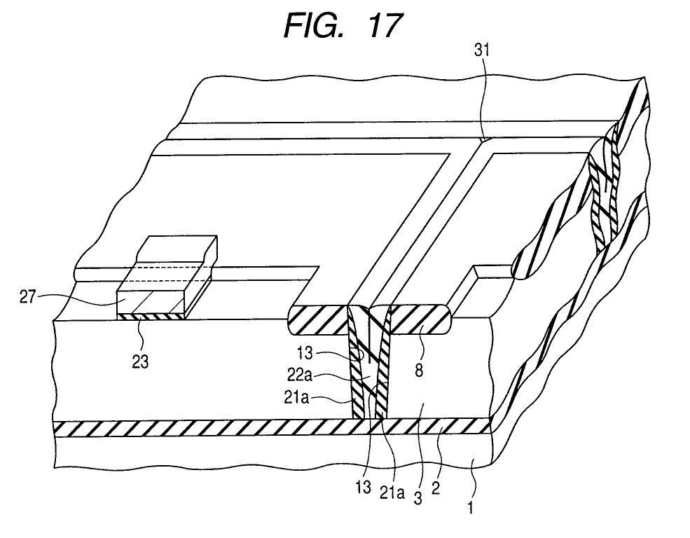

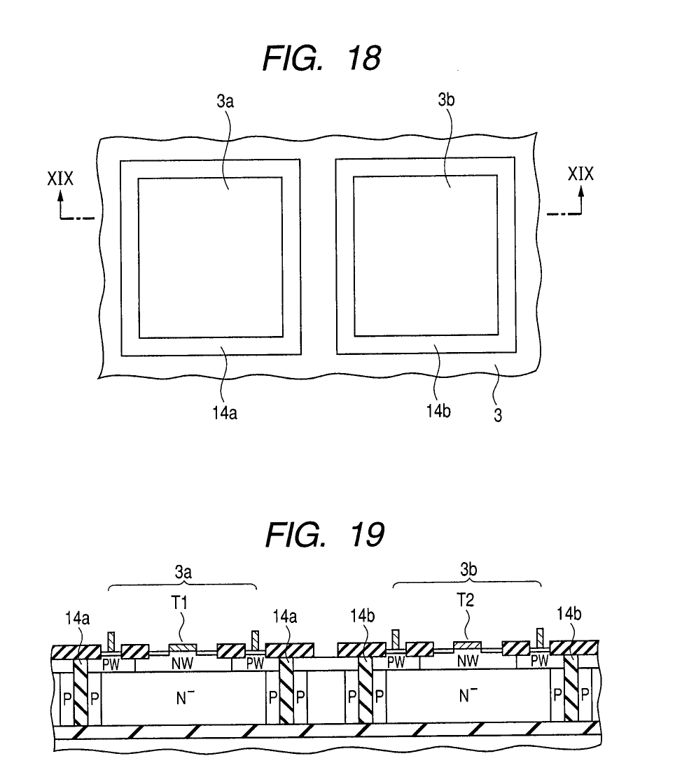

Apart from the above, as illustrated in FIG. 17, in a semiconductor device wherein no protecting film 28 is formed at a corner region of a trench 13, a washing solution, a chemical liquid or the like retains in a void 31. The retaining washing solution or chemical liquid may act a source for generating alien substances or produce an adverse effect onto the interconnections.

As described above, in the semiconductor device of the embodiment, the protecting film 28 is formed at the corner region(s) where one or more voids are said to be easily generated in the TEOS film buried in the trench 13, thereby making it possible to restrain the generation of inconveniences resulting from a washing solution, a chemical liquid or the like that retains the void 31 to make the reliability of the semiconductor device high.

About the semiconductor device of the embodiment, the case where the protecting film 28 is formed in the same step in which the gate electrode 27 is formed has been described as an example. However, the protecting film 28 may be formed in a step different from the step of forming the gate electrode 27. For example, when the protecting film is formed immediately after the void is made exposed, a washing solution, a chemical liquid or the like can be hindered from invading the void in the washing step or etching step conducted up to the formation of the gate electrode 27. Thus, the semiconductor device can gain a higher reliability. The protecting film 28 may be an insulating film other than any conductive film.

About the semiconductor device of the embodiment, the T-shaped intersection region of the trench 13 has been described as an example of a trench corner region where avoid may be made. However, this T-shaped intersection region makes its appearance actually in a case where two rectangular trenches are made adjacent to each other to make an attempt for reducing the occupation area of semiconductor elements in order to make the semiconductor device small in size.

In many cases, plural trenches that surround respective element formation regions where predetermined semiconductors are formed are generally arranged apart from each other. As illustrated in, for example, FIGS. 18 and 19, the following trenches are supposed: two rectangular trenches 14a and 14b which surround respective element formation regions 3a and 3b where high voltage-resistant semiconductor elements T1 and T2 are formed and which are made apart from each other.

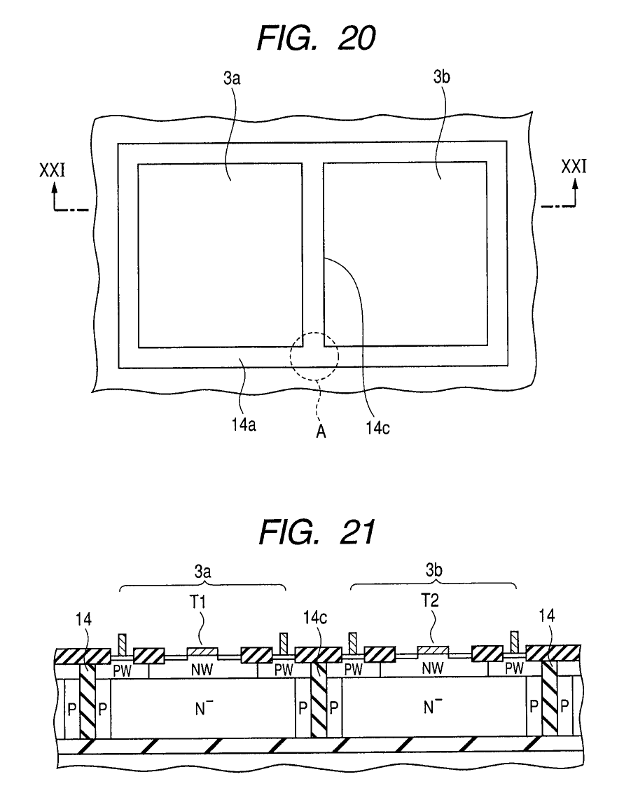

In the case of changing this arrangement pattern to an arrangement pattern wherein the two trenches 14a and 14b are made adjacent to each other so as to make two opposing sides of the two trenches 14a and 14b common to each other, thereby giving a common trench region 14c, a T-shaped intersection makes it appearance, as illustrated in FIGS. 20 and 21, at a region (in a circle A represented by a dot line) where the resultant common trench region 14c intersects the other trench region.

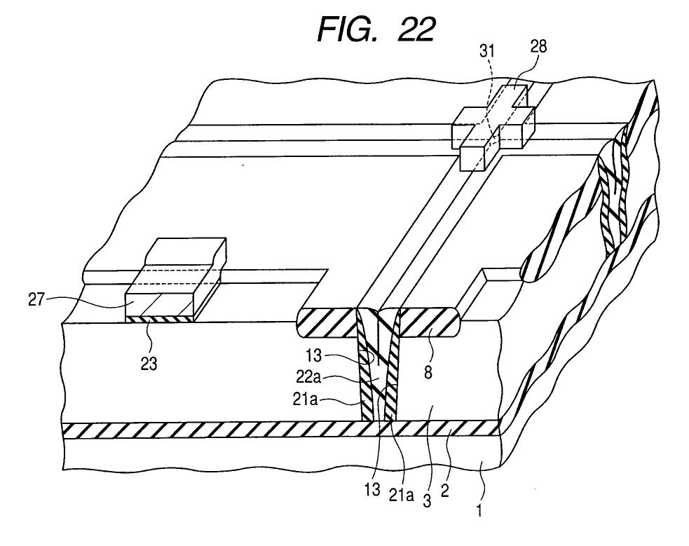

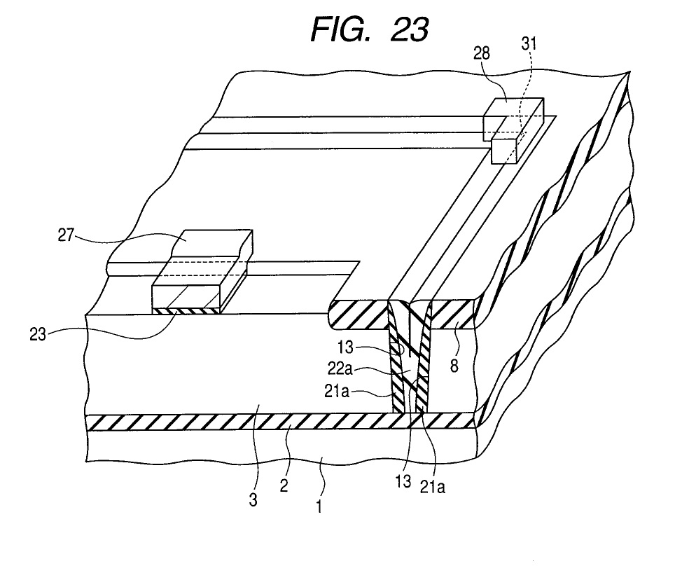

A void may be made at the following region besides the T-shaped intersection region of the trenches, as illustrated in FIG. 22: a cross intersection region where trench regions each having a predetermined width are made substantially orthogonal to each other, this cross intersection making its appearance in the case of making four rectangular trenches adjacent to each other. Additionally, it is feared that as illustrated in FIG. 23, a void is made also at an L-shaped bent region, where a trench is bent. Accordingly, as illustrated in each of FIGS. 22 and 23, when a protecting film 28 is formed at the cross intersection region or L-shaped bent region of the trench(es), the reliability of the semiconductor device can be certainly kept.

As described above, by forming a protecting film at T-shaped or cross intersection regions or L-shaped bent regions of trenches, where one or more voids may be made, it is possible to restrain the generation of inconveniences resulting from a washing solution, a chemical liquid or the like that retains in the void(s). Thus, the reliability of the semiconductor device can be certainly kept.

### Modification Example

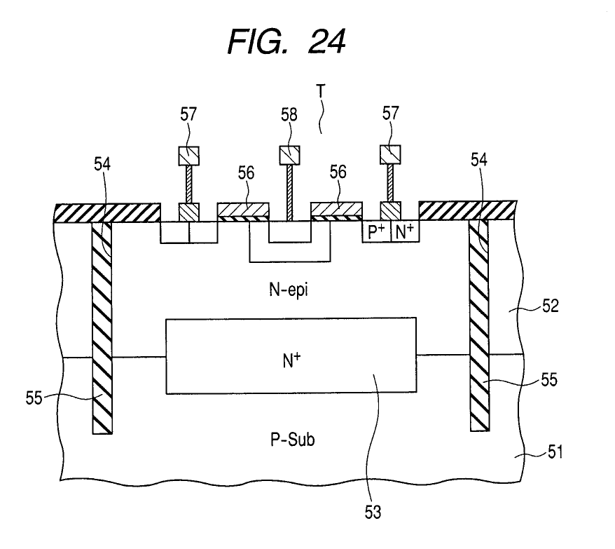

About the semiconductor device of the embodiment, the SOI substrate has been described as an example of the substrate. However, the substrate to be used may be an ordinary silicon semiconductor substrate besides the SOI substrate. In this case, as illustrated in FIG. 24, an epitaxial layer 52 is formed over the surface of a semiconductor substrate 51. On the epitaxial layer 52 are formed high voltage-resistant MOS transistors T each having a gate electrode 56, a source electrode 57 and a drain electrode 58. Between the epitaxial layer 52 and the semiconductor substrate 51, a buried diffusion layer 53 is formed.

Trenches 54 are each formed to surround an element formation region where each of the high voltage-resistant transistors T is formed, and a TEOS film 55 is buried in the trenches 54. The trenches 54 are formed to extend from the surface of the epitaxial layer 52 via the interface between the epitaxial layer 52 and the semiconductor substrate 51 to reach a predetermined depth of the semiconductor substrate.

Also in a semiconductor device wherein this semiconductor substrate is used, by forming a protecting film in the same manner as in FIG. 16, 22 or 23 at T-shaped or cross intersection regions or L-shaped bent regions of the trenches 54, it is possible to restrain the generation of inconveniences resulting from a washing solution, a chemical liquid or the like that retains in the voids. Thus, the semiconductor device can gain a higher reliability.

The place where the protecting film is formed is not limited to any T-shaped or cross intersection region, or any L-shaped bent region. When a buried film is formed in trenches, the formation of the protecting film at pattern regions of the trenches where voids may be generated makes it possible to keep the reliability of the semiconductor device certainly even when voids are generated therein.

What is claimed is:

1. A semiconductor device comprising:
an element formation region formed in a main surface of a semiconductor substrate;
a trench formed to surround the element formation region;
a buried film formed in the trench; and
a protective film formed to cover a region of the buried film that is buried in a corner region of the trench.

2. The semiconductor device according to claim 1,
wherein the trench has a predetermined width to surround a rectangular element formation region as the element formation region, and
wherein the corner region comprises at least one of an intersection region where plural regions of the trench that each have the predetermined width and are each extended to intersect each other, and a bent region where a region of the trench that has the predetermined width and is extended is bent.

3. The semiconductor device according to claim 1, wherein the buried film is a TEOS film.

4. The semiconductor device according to claim 1,
wherein the element formation region is equipped with an interconnection that is made from a predetermined electroconductive film, and
wherein the protective film is made from the same film which the conductive film is made from.

5. The semiconductor device according to claim 4, wherein the protective film is arranged in a planar form inside the trench.

6. The semiconductor device according to claim 1, wherein the protective film is formed to cover a void generated in the buried film.
